(19) United States
(12) Patent Application Publication
(10) Pub. No.: US 2004/0150063 A1
(43) Pub. Date: Aug. 5, 2004

(54) Package structure for an optical image sensor

(76) Inventor: Katsumi Yamamoto, Shanghai (CN)

Correspondence Address: PERKINS COIE LLP, PATENT-SEA, P.O. BOX 1247, SEATTLE, WA, 98111-1247, US

(21) Appl. No.: 10/745,333

(22) Filed: Dec. 23, 2003

Related U.S. Application Data
(60) Provisional application No. 60/439,140, filed on Jan. 10, 2003.

(51) Int. Cl. H01L 21/00; H01L 31/0232

(52) U.S. Cl. 257/433; 257/432; 438/48; 438/64; 438/65

(57) ABSTRACT

A package structure for an image sensor and method of manufacturing same are disclosed herein. The image sensor is encapsulated by, among others, a transparent lid, tape, and bottom cap. The thickness of the package structure is flexible and the package structure is amendable to tape automated bonding.

### CROSS REFERENCE TO RELATED APPLICATIONS

This application claims the benefit of provisional U.S. Patent Application No. 60/439,140, filed Jan. 10, 2003, which is hereby incorporated by reference in its entirety.

### BACKGROUND

The present invention relates generally to integrated circuits. More particularly, the present invention relates to packaging of integrated circuits.

Image sensors or imaging devices in integrated circuit form include an optical active area to receive light from the environment or an external light source. To protect the image sensors, especially the optical active areas, from physical damage, environmental contaminants, and/or alignment changes, the image sensors are typically surrounded by a shell, i.e., a package, that includes a transparent cover over the optical active areas. The package may also include a base, adhesive, optical components (e.g., micro lenses), and electrical leads to provide a functional image sensor chip package.

As integrated circuits become denser and image sensors get smaller, the packaged image sensors are also getting smaller. However, as the package size is reduced, maintaining sensor performance and throughput, among others, becomes difficult.

Thus, there is a need for a reduced package size for an image sensor. There is a further need for a reduced package size that does not adversely affect sensor performance or throughput. There is still a further need for a small package for an image sensor that provides a cost reduction of the assembling materials.

### SUMMARY

An embodiment of the invention relates to a chip package. The package includes a first layer, a second layer, and a third layer. The first layer includes a cavity and an integrated circuit is positioned within the cavity. The second layer is below the integrated circuit and the first layer, the second layer being secured to the integrated circuit and the first layer so that the integrated circuit is secured from the bottom within the cavity. The third layer is above the integrated circuit and secures from the top the integrated circuit within the cavity. Thee third layer comprises a transparent material.

Another embodiment of the invention relates to a method for fabricating a package structure for an integrated circuit. The method includes forming a layer including a set of openings over a wafer, and forming a top layer over the integrated circuits. The method further includes thinning the wafer and forming a bottom layer under the integrated circuits. The set of openings coincide with the locations of integrated circuits formed on the wafer. A combined thickness of the layer, top layer, and bottom layer is less than approximately 1.0 millimeter. Each of the integrated circuits is configured to be an image sensor.

Still another embodiment of the invention relates to a method for fabricating a chip scale package. The method includes positioning an image sensor chip upside down within a cavity formed by a first layer, a second layer, a third layer, a first protrusion, and a second protrusion. The first protrusion is placed over an edge of the first layer, and the second protrusion is placed over an edge of the second layer. The third layer is placed over the first and second layers. An opening included in the third layer, the first and second protrusions, and the edges of the first and second layers comprise the cavity.

### BRIEF DESCRIPTION OF THE DRAWINGS

The exemplary embodiments will become more fully understood from the following detailed description, taken in conjunction with the accompanying drawings, wherein like reference numerals denote like elements, in which:

FIG. 1 is a cross-sectional view of one embodiment of a package structure for an IC image sensor.

FIG. 2 is a cross-sectional view of one embodiment of a fabrication step of the package structure of FIG. 1.

FIG. 3 is a cross-sectional view of another embodiment of a fabrication step of the package structure of FIG. 1.

As is conventional in the field of circuit representation, sizes of electrical components are not drawn to scale, and various components can be enlarged or reduced to improve drawing legibility. Component details have been abstracted in the figures to exclude details such as position of components and certain precise connections between such components when such details unnecessarily obscures discussion of the invention.

### DETAILED DESCRIPTION

A thin package structure for an integrated circuit (IC) image sensor and method of manufacturing the thin package structure are disclosed herein. The packaged image sensor can have a total thickness of less than 1.0 millimeter (mm). The packaged image sensor is suitably configured for tape automated bonding (TAB).

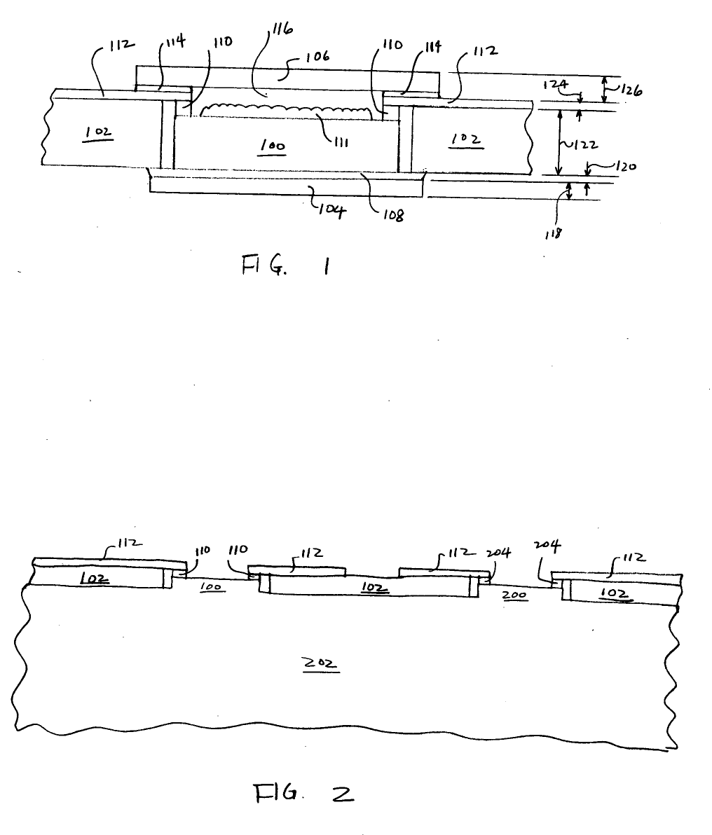

Referring to FIG. 1, a cross-sectional view of one embodiment of a package structure for an IC image sensor is shown. An IC image sensor 100, also referred to as a chip, is encased on all sides by a tape 102, a bottom cap 104, and a transparent top or lid 106. An adhesive layer 108 is located above the bottom cap 104, and each of the image sensor 100 and the tape 102 is located above the adhesive layer 108. The image sensor 100 is substantially centered above the adhesive layer 108. The tape 102 comprises a layer with a cutout or opening configured such that at least the edges of the opening are located above the adhesive layer 108. The adhesive layer 108 is configured to secure the bottom cap 104 to each of the tape 102 and the image sensor 100.

A color filter 111 is located above an optical active area of the image sensor 100. The bumps 110 are located on the top periphery of the image sensor 100. The bumps 110 are configured to provide an electrical pathway between a metal layer 112 and the image sensor 100. The metal layer 112 is supported above the tape 102. The metal layer 112 comprises a set of conductive leads (e.g., a copper pattern) configured to align with the pins or outputs/inputs of the image sensor 100.

Above the image sensor 100 is the transparent lid 106. The transparent lid 106 is supported by and secured to the metal layer 112 via an adhesive layer 114. The transparent lid 106 is positioned over at least the optical active area of the image sensor 100. Light or radiation is detected by the image sensor 100 via the transparent lid 106, a gap 116, and the color filter 111.

The tape 102 can comprise a polyimide or glass epoxy material. The bottom cap 104 can comprise a metal or resin material. The transparent lid 106 can comprise a glass, plastic, polymer, or a variety of other materials that is optically transparent and sturdy enough to serve as a protective barrier without unduly degrading the sensor performance.

Each of the bumps 110 and the metal layer 112 is comprised of a conductive material. The metal layer 112 may comprise a set of thin conductive strips that have been etched or stamped to form conductive leads or electrodes. As an example, the conductive strips may be a TAB structure. Alternatively, the metal layer 112 may be configured for connection to a TAB structure. Adhesive layers 108 and 114 can be an epoxy type material that is activated by certain application of light, pressure, and/or heat.

In one embodiment, a thickness 118 of the bottom cap 104 is approximately 0.2 mm, a thickness 120 of the adhesive layer 108 is approximately 0.012 mm, and a thickness 122 of the tape 102 is approximately 0.6 mm. A thickness 124 of the metal layer 112 is approximately 0.012 mm, and a thickness 126 of the adhesive layer 114 and the transparent lid 106 combined is approximately 0.2 mm. In another embodiment, the total thickness of the packaged structure is less than 1.0 mm, such as being approximately 0.9 mm. In still another embodiment, the total thickness of the packaged structure can be less than approximately 0.65 mm by grinding down the bottom side of the wafer of the image sensor 100 so that the tape 102 can be less than 0.6 mm thick.

Although not shown in FIG. 1, the color filter 111 can comprise a variety of optical components. For example, the color filter 111 may include a micro lens, a collimator, etc. The transparent lid 106 can also comprise one or more optical components such as a polarizer. The gap 116 may be filled with gaseous or liquid materials to further enhance optical properties, temperature characteristics, or other performance characteristics of the image sensor 100.

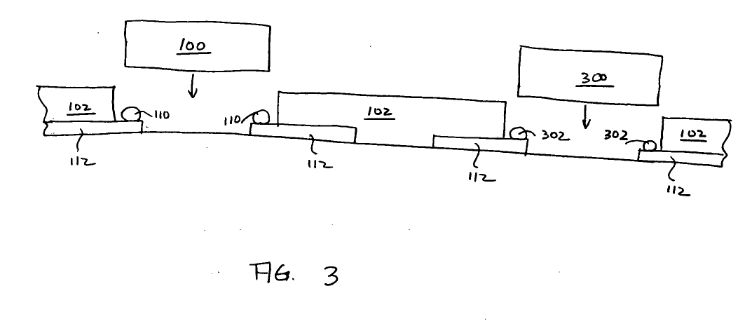

In FIG. 2, one embodiment of a cross-sectional view of a fabrication step of the package structure of FIG. 1 is shown. A plurality of image sensors, such as the image sensor 100 and an image sensor 200, are formed on a wafer or substrate 202. The tape 102 is configured to be a layer of material with a matrix of openings aligned with the positions of the image sensors at the wafer 202. The tape 102 is placed over the wafer 202 such that the openings coincide with the image sensors. Then the bumps, such as the bumps 110 and bumps 204, are applied to the image sensors. The bumps are followed by the metal layer 112. Next, the color filter 111 is inserted and the transparent lid 106 is affixed as the top layer using the adhesive layer 114 (not shown).

Once the cavity, leads, and top cover for each of the image sensors have been formed, the backside or bottom of the wafer 202 is ground down to make the wafer thinner. Then an adhesive layer is laid down and bottom caps are affixed to the bottom of the thinned wafer 102. Lastly, a die cutting machine is used to cut the wafer 202 into individual packaged image sensors.

The various layers comprising the package structure are applied, positioned, or shaped using known photolithographic processes and equipment. For example, the adhesive is applied using a spin coating process. The metal layer 112 is lithographically patterned and etched to form the conductive leads. The cavities formed by the tape 102 may also be lithographically patterned and etched.

In another embodiment, the package structure may be fabricated “upside down,” as shown in a cross-sectional view in FIG. 3. In FIG. 3, the metal layer 112, bumps 110, and bumps 302 are fabricated first to form appropriate cavities for receiving the image sensors. A temporary substrate or other type of base may be provided below the metal layer 112. After the image sensors, such as the image sensor 100 and an image sensor 300, are secured to their respective bumps, the adhesive layer 108 and a bottom cap for each of the image sensors can be laid down.

Once the bottom layers of the package structures are formed and secured, this partially fabricated structure can be flipped over so that the adhesive layer 114 and transparent lids for each of the image sensors can be laid down. Lastly, a cutting machine is used to cut the matrix of package structures into individual packaged image sensors.

Although the image sensors 100 and 300 in FIG. 3 are shown thinned and individually cut from a wafer, the image sensors may alternatively be positioned into their respective cavities as a monolithic wafer. The image sensors may be secured to the bumps within each cavity, and then the bottom side of the wafer (i.e., the side of the wafer furthest away from the image sensors) may be thinned.

Similar to the embodiment illustrated in FIG. 2, the various layers in FIG. 3 are also applied, positioned, or shaped using known photolithographic processes and equipment. Optical component(s), such as the color filter 111, are also included within the cavities and positioned at the optical active areas of the image sensors.

In this manner, a thin package structure for an image sensor and manufacture of same are disclosed herein. The thickness of the package structure may be modified depending on application requirements without having to redesign the package structure or the fabrication process. A variety of optical component(s) for a given type of image sensor or a variety of different image sensors may also be implemented in the package structure.

Unless the context clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also include the plural or singular number, respectively. Additionally, the words “herein,” “above,” “below,” and words of similar import, when used in this application, shall refer to this application as a whole and not to any particular portion of the application. When the claims use the word “or” in reference to a list of two or more items, that word covers all of the following interpretations of the word: any of the items in the list, all of the items in the list, and any combination of the items in the list.

From the foregoing, it will be appreciated that specific embodiments of the invention have been described herein for purposes of illustration, but that various modifications may be made without deviating from the spirit and scope of the invention. For example, although certain materials are discussed herein, other materials may be implemented as long as they provide similar characteristics and functionalities. Accordingly, the invention is not limited except as by the appended claims.

I/We claim:

1. A chip package, comprising:
a first layer including a cavity, an integrated circuit positioned within the cavity;
a second layer configured below the integrated circuit and the first layer, the second layer being secured to the integrated circuit and the first layer so that the integrated circuit is secured from the bottom within the cavity; and
a third layer configured above the integrated circuit and securing from the top the integrated circuit within the cavity, the third layer comprising a transparent material.

2. The chip package of claim 1, further comprising:
an optical component provided between the integrated circuit and the third layer; and
leads electrically coupled to the integrated circuit, the lead provided between the third layer and the first layer.

3. The chip package of claim 2, wherein the second layer is secured to the first layer by an adhesive, and the third layer is secured to the leads by an adhesive.

4. The chip package of claim 2, wherein the optical component is a filter.

5. The chip package of claim 1, wherein a thickness of the chip package is less than approximately 1.0 millimeter.

6. The chip package of claim 1, wherein a thickness of the chip package is less than approximately 0.65 millimeter.

7. The chip package of claim 1, wherein each of the second layer and the third layer is positioned over the cavity to secure the integrated circuit within the cavity.

8. The chip package of claim 1, wherein the integrated circuit is an image sensor chip.

9. A method for fabricating a package structure for an integrated circuit, the method comprising:
forming a layer including a set of openings over a wafer, the set of openings coinciding with the locations of integrated circuits formed on the wafer;
forming a top layer over the integrated circuits;
thinning the wafer; and
forming a bottom layer under the integrated circuits, wherein a combined thickness of the layer, top layer, and bottom layer is less than approximately 1.0 millimeter, and each of the integrated circuits is configured to be an image sensor.

10. The method of claim 9, wherein the top layer comprises a transparent material.

11. The method of claim 9, further comprising:
affixing the top layer; and
affixing the bottom layer so that each of the integrated circuits is encapsulated within the openings of the layer.

12. The method of claim 9, further comprising:
cutting the layered wafer into individual package structures.

13. The method of claim 9, further comprising:
forming bumps over the top periphery of the integrated circuits; and
forming conductive leads at least partially over the layer and in electrical contact with the bumps.

14. The method of claim 13, wherein at least one of forming bumps and forming conductive leads includes utilizing tape automated bonding (TAB).

15. A method for fabricating a chip scale package, the method comprising:
positioning an image sensor chip upside down within a cavity formed by a first layer, a second layer, a third layer, a first protrusion, and a second protrusion, wherein the first protrusion is placed over an edge of the first layer, the second protrusion is placed over an edge of the second layer, and the third layer is placed over the first and second layers, and wherein an opening included in the third layer, the first and second protrusions, and the edges of the first and second layers comprise the cavity.
